(19) United States
(12) Patent Application Publication
(10) Pub. No.: US 2026/0144144 A1
(43) Pub. Date: May 21, 2026

(54) SENSOR MONITORING FOR SYSTEM DIE

(71) Applicant: Advanced Micro Devices, Inc., Santa Clara, CA (US)

(72) Inventors: John Andrew Edward Burks, Fort Collins, CO (US); Justin Allan Coppin, Fort Collins, CO (US); Regina T. Schmidt, Santa Clara, CA (US)

(73) Assignee: Advanced Micro Devices, Inc., Santa Clara, CA (US)

(21) Appl. No.: 18/952,610

(22) Filed: Nov. 19, 2024

(51) Int. Cl. H01L 25/065; G01R 31/28; H01L 21/66; H01L 25/18

(52) U.S. Cl. CPC H10W 90/00; G01R 31/2829; H10P 74/277; H10W 90/284; H10W 90/297; H10W 90/722

(57) ABSTRACT

The disclosed device includes a base die and one or more stack die, and includes various components that monitor various locations on the base die and the one or more stack die. The components include sensors that provide signals including sensor data that are compared to a threshold by a controller of the base die. If the sensor data satisfies the threshold, the controller can transmit a signal to cause the base die, the one or more stack die, or a combination thereof, to perform an action, such as to throttle operations intended for the base die and one or more stack die. Various other methods, systems, and computer-readable media are also disclosed.

### BACKGROUND

As demand for semiconductor devices that provide high-processing capability while simultaneously providing efficient use of space continues to increase, the use of multi-die semiconductor packages to satisfy such demands has also increased. Such multi-die semiconductor packages can include a base die and any number of stack die that can be stacked vertically on top of the base die within the semiconductor package. The base die typically serves as the primary die of the package that contains the core functions of the device in which the multi-die semiconductor package is installed. The stack die that are stacked on top of the base die often provide additional processing, storage, or other capabilities to complement, supplement, or provide redundancy for the functionality supported by the base die.

### BRIEF DESCRIPTION OF THE DRAWINGS

The accompanying drawings illustrate a number of exemplary implementations and are a part of the specification. Together with the following description, these drawings demonstrate and explain various principles of the present disclosure.

FIG. 1 is a schematic diagram of an exemplary system for providing sensor monitoring for system die according to implementations of the present disclosure.

FIG. 2 is a schematic diagram of an exemplary architecture for sensor monitoring for system die according to implementations of the present disclosure.

FIG. 3 is a schematic diagram of another exemplary architecture for sensor monitoring for system die according to implementations of the present disclosure.

FIG. 4 is a flow diagram of an exemplary method for conducting sensor monitoring for system die according to implementations of the present disclosure.

Throughout the drawings, identical reference characters and descriptions indicate similar, but not necessarily identical, elements. While the exemplary implementations described herein are susceptible to various modifications and alternative forms, specific implementations have been shown by way of example in the drawings and will be described in detail herein. However, the exemplary implementations described herein are not intended to be limited to the particular forms disclosed. Rather, the present disclosure covers all modifications, equivalents, and alternatives falling within the scope of the appended claims.

### DETAILED DESCRIPTION

The present disclosure is generally directed to sensor monitoring of system die, such as base die and stack die of a semiconductor package of a device or system. As the use of computing devices to perform various types of operations continues to increase, the performance, stability, and health of the die are of concern when ensuring optimal handling of various operations of the system. For example, if the base die or the stack die of the semiconductor package are overloaded with operations such that the die or surrounding areas reach unsafe temperatures or experience other conditions, potential damage to the die or other components of the system can occur. Implementations of the present disclosure facilitate detection of conditions and initiation of actions to counteract or minimize potential harmful effects that can result from the presence of such conditions in, on, or about the semiconductor package. As will be explained in greater detail below, implementations of the present disclosure can perform sensor monitoring of system die by utilizing a controller of a semiconductor device to obtain sensor data from any number of sensors located at, on, and/or in proximity to the base die and/or stack die of a semiconductor package. Once the sensor data is received by the controller and/or other system components, the controller and/or other system components can compare the sensor data to a threshold(s) to determine whether a condition exists. If the sensor data satisfies the threshold, the controller and/or other system components can generate and transmit a signal(s) to initiate one or more actions for the base die and/or stack die for which the sensor data satisfied the threshold.

In certain implementations, a device for providing sensor monitoring for system die is provided. The device can include a stack die that can include one or more stack die sensors for measuring sensor data associated with the stack die. The device can also include a base die that includes one or more base die sensors. The base die controller can receive one or more first signals including sensor data from the one or more base die sensors and/or one or more sensor die sensors. In certain implementations, the base die controller can compare the received sensor data to a threshold(s). If the sensor data satisfies the threshold, the controller can transmit one or more second signals to the base die and/or the stack die to initiate one or more actions for the base die and/or the stack die.

In certain implementations, the base die controller can monitor the one or more stack die sensors and/or the one or more base die sensors. In certain implementations, the base die controller can transmit an activation signal to activate operation of the one or more base die sensors and/or one or more sensor die sensors. In certain implementations, the base die controller can transmit a deactivation signal to deactivate operation of the one or more base die sensors and/or one or more sensor die sensors. In certain implementations, the base die controller can receive an instruction associated with the one or more first signals to initiate the one or more first actions from a firmware register of the system. In certain implementations, the one or more first actions can include throttling one or more operations intended for the base die, the stack die, or a combination thereof. In certain implementations, the one or more first actions can include deactivating one or more components of the base die and/or stack die.

In certain implementations, the device can further include a stack die controller that can monitor the one or more stack die sensors. The stack die controller can receive a signal of the one or more first signals including the sensor data from the stack die. In certain implementations, the stack die controller can compare the sensor data from the one or more stack die sensors to a stack die threshold. If the sensor data from the one or more stack die sensors satisfies the stack die threshold, the stack die controller can transmit one or more signals to initiate one or more actions for the stack die. In certain implementations, the stack die controller can compare the sensor data from the one or more stack die sensors to the stack die threshold, and, if the sensor data from the one or more stack die sensors does not satisfy the stack die threshold, the stack die controller can maintain a current state of the stack die or a planned state for the stack die.

In certain implementations, the device can include one or more through silicon vias to facilitate communication between the base die and the stack die.

In certain implementations, the threshold can correspond to a temperature threshold for the base die and/or the stack die.

In certain implementations, a system for providing sensor monitoring for system die is provided. The system includes a device, such as a computing device or other device, and a package installed on the device, such as a semiconductor package. The package can include a base die that includes one or more base die sensors and a base die controller. In certain implementations, the base die controller can receive one or more first signals including sensor data from the one or more base die sensors, one or more stack die sensors of a stack die in communication with the base die, or a combination thereof. The base die controller can compare the sensor data to a threshold. If the sensor data satisfies the threshold, the base die controller can transmit at least one second signal or one or more second signals to the base die, the stack die, or a combination thereof, to initiate one or more first actions for the base die, the stack die, or a combination thereof.

In certain implementations, the base die further includes a processor, a memory, a communication module, or a combination thereof. In certain implementations, the base die controller can communicate with a separate base die from a separate system, and can offload, if the sensor data satisfies the threshold, one or more operations intended for the base die, the stack die, or a combination thereof, to the separate base die.

In certain implementations, the base die controller can modify the threshold that is utilized for comparison to the sensor data.

A system for providing sensor monitoring for system die is provided. The system includes a memory and a device communicatively linked to the memory. In certain implementations the device can include a base die that can include one or more base die sensors and a base die controller configured to perform various functionality. In certain implementations, the base die controller can receive one or more first signals including sensor data from the one or more base die sensors, one or more stack die sensors of a stack die in communication with the base die, or a combination thereof. In certain implementations, the base die controller can compare, such as by utilizing instructions from the memory, the sensor data to a threshold. In certain implementations, the base die controller can transmit, if the sensor data satisfies the threshold, one or more second signals to the base die, the stack die, or a combination thereof, to initiate one or more first actions for the base die, the stack die, or a combination thereof. In certain implementations, the base die controller can provide the first signal, the second signal, or a combination thereof, to the memory for storage.

A method for providing sensor monitoring for system die is provided. The method can include receiving, by a base die including one or more base die sensors, one or more first signals including sensor data from the one or more base die sensors, one or more stack die sensors of a stack die in communication with the base die, or a combination thereof. The method can include comparing the sensor data to a threshold. The method can include transmitting, if the sensor data satisfies the threshold, one or more second signals to the base die, the stack die, or a combination thereof, to initiate one or more first actions for the base die, the stack die, or a combination thereof.

In certain implementations, the method can include communicating, by utilizing the base die, with the stack die via an interposer. The method can include continuing a current state for the base die, the stack die, or a combination thereof, if the sensor data does not satisfy the threshold. The method can include obtaining additional sensor data from the one or more base die sensors, the one or more stack die sensors, or a combination thereof. The method can include comparing the additional sensor data to the threshold. The method can include transmitting, if the additional sensor data does not satisfy the threshold, one or more third signals to the base die, the stack die, or a combination thereof, to return the base die, the stack die, or a combination thereof, to a prior operational state.

Features from any of the implementations described herein can be used in combination with one another in accordance with the general principles described herein. These and other implementations, features, and advantages will be more fully understood upon reading the following detailed description in conjunction with the accompanying drawings and claims.

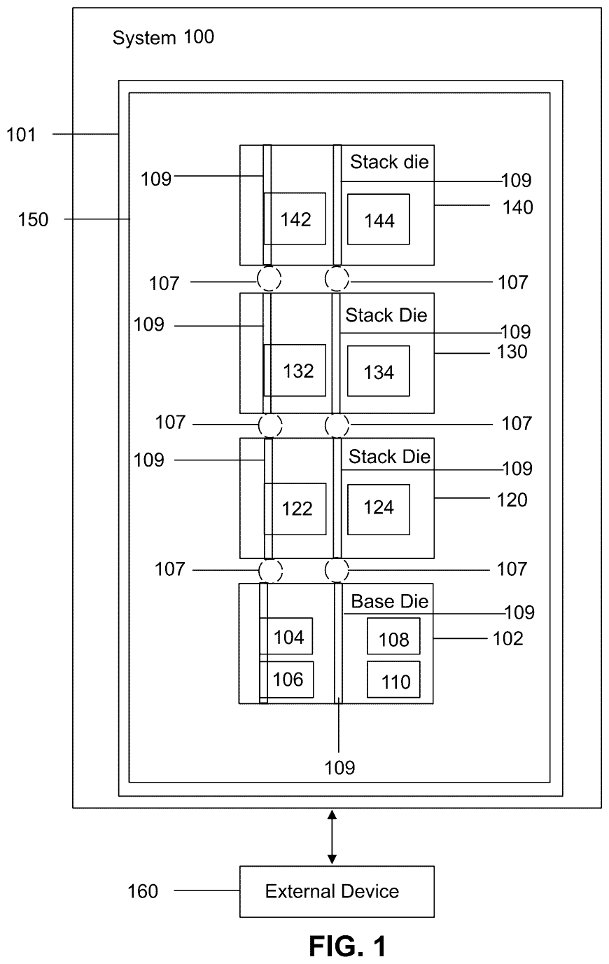

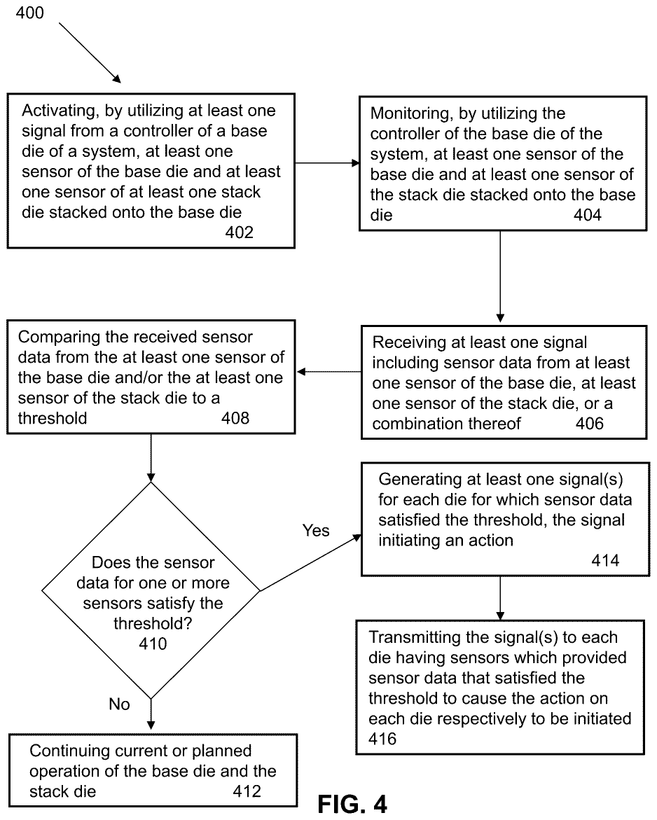

The following will provide, with reference to FIGS. 1-4, detailed descriptions of sensor monitoring for system die. Detailed descriptions of example systems will be provided in connection with FIGS. 1, 2, and 3. Detailed descriptions of corresponding methods will also be provided in connection with FIG. 4. Any of the components, functionality, features, and/or other aspects of the systems and methods of FIGS. 1, 2, 3, and 4 can be combined together to form various implementations of the present disclosure.

FIG. 1 is a schematic block diagram of an exemplary system 100 for providing sensor monitoring for system die. In certain implementations, the system 100 can correspond to any number of devices, communication links, programs, components, printed circuit boards, and/or any other systems and devices. In certain implementations, the system 100 can include any combination of devices, communication links, programs, components, printed circuit boards, and/or any other combinations of systems and devices. Computing device 101 can correspond to a computing device, such as a desktop computer, a laptop computer, a server, a tablet device, a mobile device, a smartphone, a wearable device, an augmented reality device, a virtual reality device, a network device, an electronic device, and/or other device. In certain implementations, the computing device 101 can include any number of processors, memories, communication devices, printed circuit boards, and/or other components. The computing device 101 can be configured to perform operations, such as, but not limited to, obtain data, process data, store data, transmit data, modify data, perform any action with respect to data, or a combination thereof.

In certain implementations, the computing device 101 can include a semiconductor package 150. In certain implementations, the semiconductor package 150 can include an enclosure that houses a base die 102 and any number of stack die 120, 130, 140 that can be stacked onto the base die 102. The stack die 120, 130, 140, for example, can be stacked vertically on top of the base die 102 within the semiconductor package 150, however, other configurations for stacking can also be utilized. In certain implementations, the base die 102 can be connected to stack die 120 via a bump 107 (e.g., microbumps made of solder material) and/or other component (e.g., metal connection) that is used to connect bond pads on the surface of the base die 102 to the corresponding bond pad on the stack die 120. A bump 107 or other component (e.g., metal connection) can be utilized to create electrical connections between the bond pads of dies adjacent to each other in the stack of the semiconductor package 150. Similarly, the stack die 120 can be connected to stack die 130 via a bump 107 and/or other component that that is used to connect bond pads on the surface of the stack die 120 to the corresponding bond pad on the stack die 130. As a further example, the stack die 130 can be connected to stack die 140 via a bump 107 and/or other component that is used to connect bond pads on the surface of the stack die 130 to the corresponding bond pad on the stack die 140. In certain implementations, any number of microbumps 107 can exist between each pair of die within the stack. In certain implementations, a microbump 107 can be positioned in between a pair of die, such as, but not limited to, wherever a through silicon-via 109 begins or ends.

In certain implementations, each of the base die 102, the stack die 120, the stack die 130, and/or the stack die 140 can include interconnects that pass through the corresponding die so as to provide a direct electrical path between each layer in the stack of the semiconductor package 150. In certain implementations, the interconnects, for example, can be through-silicon vias (e.g., through-silicon vias 109) that extend within at least a portion of the height of each of the base die 102, the stack die 120, the stack die 130, and/or the stack die 140. In certain implementations, there can be any number of through-silicon vias 109 extending through the base die 102, the stack die 120, the stack die 130, and/or the stack die 140. In certain implementations, the base die 102 and the stack die 120, 130, 140 can be connected to each other directly using through-silicon vias 109 without using the microbumps 107. The through-silicon vias 109 can include conductive material, such as, but not limited to, copper that can be utilized to connect a bond pad on one die to a bond pad on another die within the stack. Through-silicon vias 109 can be utilized to enable rapid communication between each of the die layers in the semiconductor stack 150 and can be utilized to facilitate transmission of signals, such as signals including data, sensor measurements, commands, and/or any other type of information that can be carried via signals. In certain implementations, the through-silicon vias 109 can be utilized for implementations including 3D integrated circuits.

In certain implementations, the base die 102 can be the primary component of the semiconductor package 150 that can be utilized to control the operation of the semiconductor package 150 and communicate with external devices, such as external device 160. In certain implementations, the base die 102 can communicate with any of the components of the computing device 101, receive instructions from other components of the computing device 101 (e.g., to process data, store data, retrieve data, transmit data, etc.), provide results to other components of the computing device 101, or a combination thereof. Additionally, the base die 102 can interact with each of the stack die 120, 130, 140, such as by transmitting instructions to the stack die 120, 130, 140 (e.g., to store data, process data, retrieve data, etc.). In certain implementations, the base die 102 can activate or deactivate any of the stack die 120, 130, 140. In certain implementations, the base die 102 can obtain information associated with the current performance and/or operational states of the stack die 120, 130, 140.

In certain implementations, the base die 102 can be made of silicon and can include any number of transistors, diodes, integrated circuits, and/or other components. For example, the base die 102 can include any number and/or combination of integrated circuits, such as, but not limited to, processors (e.g., microprocessors), memories, microcontrollers, sensors, digital signal processors, voltage regulators, communication devices (e.g., wireless), operational amplifiers, field-programmable gate arrays, and/or any other types of integrated circuits. Illustratively, the base die 102 of FIG. 1 can include a controller 104 (e.g., which can include processor capabilities), a memory 106, a communication device 108, a sensor 110, and/or any other components. In certain implementations, the base die 102 can include any number of controllers 104, memories 106, communication devices 108, sensors 110, and/or any other components. In certain implementations, the controller 104 can execute instructions to perform various operations (e.g., store data, process data, retrieve data, communicate with stack die 120, 130 140, etc.). In certain implementations, the controller 104 can be a stack die controller if on a stack die 120, 130, 140 or a base die controller if on the base die 102. The controller 104 can also be utilized to deactivate and activate sensors (e.g., sensor 110), obtain signals containing sensor data from the sensors (e.g., sensor 110), monitor the sensors, initiate actions to be performed based on sensor data, maintain an operational state of the base die 102 and/or stack die 120, 130, 140, adjust an operational state of the base die 102, and/or stack die 120, 130, 140, and/or perform any other operations. In certain implementations, the controller 104 can include chiplets (e.g., smaller and in some examples more specialized processing units that can coordinate as a single chip), microprocessors, microcontrollers, Central Processing Units (CPUs), graphics processing units (GPUs), Field-Programmable Gate Arrays (FPGAs) that implement softcore processors, Application-Specific Integrated Circuits (ASICs), systems on chip (SoCs), digital signal processors (DSPs), Neural Network Engines (NNEs), accelerators, graphics processing units (GPUs), portions of one or more of the same, variations or combinations of one or more of the same, and/or any other suitable physical processor.

In certain implementations, the memory 106 can store data and instructions that can be retrieved and/or accessed by the controller 104. The memory 106 can represent any type or form of volatile or non-volatile storage device capable of storing data and/or computer-readable instructions. For example, the memory 106 can be flash memory, cache memory, any type of memory, or a combination thereof. In certain implementations, the communication device 108 can communicate with external devices (e.g., external device 160) and/or other components of the system 100. The memory 160 can store sensor data, threshold information for thresholds utilized for comparison purposes to sensor data, information associated with actions to be performed with regard to the semiconductor package 150, and/or any other information. In certain implementations, the communication device 108 can communicate wirelessly to other devices and can be any type of communication device. In certain implementations, the sensor 110 can be any type of sensor including, but not limited to, temperature sensors (e.g., thermistor, thermocouples, infrared sensors, integrated temperature sensors, digital thermal sensors, etc.), motion sensors, light sensors, pressure sensors, humidity sensors, accelerometers, orientation sensors (e.g., gyroscope), vibration sensors, any other type of sensors or a combination thereof. Sensors 110 located on and/or in proximity to the base die 102 can be base die sensors. In certain implementations, any number of sensors 110 can be included in the base die 102 and/or on any location of the base die 102. For example, sensors 110 can be placed on locations and/or positions on the base die 102 that are expected to be hotspots, that are near highly used components of the base die 102, that have a greater amount of circuitry for integrated circuits on the base die 102, that are at random, or a combination thereof.

In certain implementations, for example, the sensors 110 can measure and/or generate sensor data proximate to the location at which the sensors 110 are positioned. The sensor data from the sensors 110 can be provided to the controller 104 of the base die 102, such as via signals from the sensors 110. In certain implementations, the sensors 110 can be activated by the controller 104, deactivated by the controller 104, accessed by the controller 104, communicate with the controller 104, or a combination thereof. In certain implementations, the sensors 110 can communicate with any of the components of the system 100.

In certain implementations, the stack die 120, 130, 140 can be secondary components of the system 100. Much like the base die 102, the stack die 120, 130, 140 can be made of silicon and can include any number of transistors, diodes, integrated circuits, and/or other components. For example, the stack die 120, 130, 140 can include any number and/or combination of integrated circuits, such as, but not limited to, processors (e.g., microprocessors), memories, microcontrollers, sensors, digital signal processors, voltage regulators, communication devices (e.g., wireless), operational amplifiers, field-programmable gate arrays, and/or any other types of integrated circuits. Illustratively, as shown in FIG. 1, the stack die 120 can include components 122 and sensors 124, stack die 130 can include components 132 and sensors 134, and stack die 140 can include components 142 and sensors 144. In certain implementations, the components 122, 132, 142 can be processors, memories, integrated circuits, and the like. In certain implementations, any number of stack die 120, 130, 140 can be utilized with the semiconductor package 150. In certain implementations, the sensors 124, 134, 144 can be placed at any locations on the respective stack dies 120, 130, 140, such as at locations that are expected to be associated with certain types of operations, certain amounts of operations, locations where component are susceptible for failure, potential hotspot locations, any other locations, or a combination thereof. Sensors 124, 134, 144 located on and/or in proximity to stack die 120, 130, 140 can be stack die sensors. In certain implementations, the sensors 124, 134, 144 can be any type of sensors, such as the sensors described in the present disclosure.

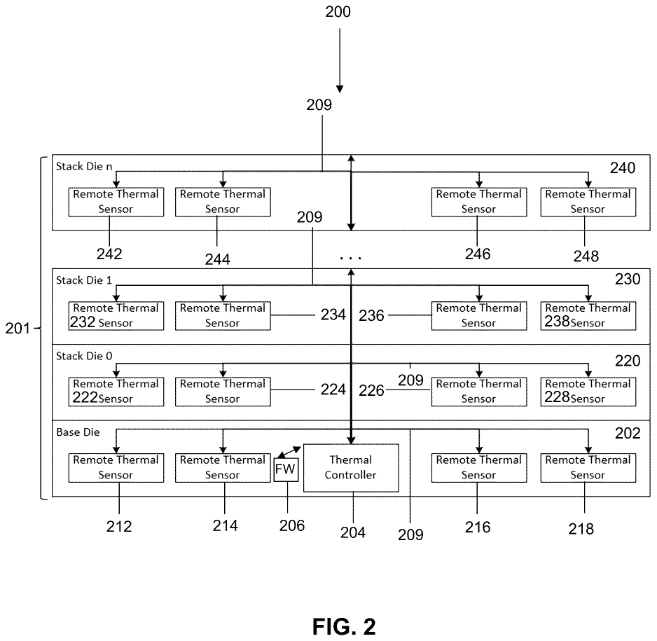

Referring now also to FIG. 2, a schematic diagram of an exemplary architecture for sensor monitoring for system die according to implementations of the present disclosure is shown. In certain implementations, the system 200 can be and/or can include the system 100, a modified version of system 100, the computing device 101, and/or the semiconductor package 150. Illustratively, FIG. 2 the system 200 can include a semiconductor device or package 201 that can include a base die 202 (e.g., which can be the same or similar as base die 102) and n number of stack die 220, 230, 240. In certain implementations, the base die 202 and the stack die 220, 230, 240 can be the same type of die, but in certain implementations, the base die 202 and the stack die 220, 230, 240 can be different types of die that are implemented via different technologies. In certain implementations, the base die 202 can include a controller 204 (e.g., the same or similar to controller 104) that can be utilized to control, activate, and/or deactivate the various sensors (e.g., sensors 212, 214,216, 218, 222, 224, 226, 228, 232, 234, 236, 238, 240, 242, 246, and 248) of the system 200. In certain implementations, the controller 204 can communicate with any of the components of the system 200, the system 100, or a combination thereof. In certain implementations, the controller 204 can receive signals from an external device (e.g., external device 160), such as signals indicating operations to be performed by the components of the base die 202, the stack die 220, the stack die 230, and/or the stack die 240. In certain implementations, the base die 202 can include any components of a traditional base die, but can also include additional components, such as a firmware register 206, which can be utilized to store instructions, signals, sensor data from sensors of the base die 202 and/or the stack die 220, 230, 240, any data and/or information generated in and/or by the system 200, or a combination thereof. In certain implementations, the firmware register 206 can be included in other components of the semiconductor package 150 and/or even on certain stack die 220, 230, 240.

In certain implementations, the base die 202 can include any number and/or type of sensors, such as, but not limited to, sensors 212, 214, 216, 218. In certain implementations, the sensors can be temperature sensors that can measure the temperature in a vicinity of the location at which the sensors 212, 214, 216, 218 are positioned. For example, illustratively in FIG. 2, four temperature sensors 212, 214, 216, 218 are shown and are positioned at different locations on the base die 202 respectively. Each sensor 212, 214, 216, 218 can measure the temperature (and/or other types of sensor data) in a vicinity of the corresponding location that each sensor 212, 214, 216, 218 is located. In certain implementations, the sensors 212, 214, 216, 218 can be any other type of sensors, such as, but not limited to, motion sensors, light sensors, pressure sensors, humidity sensors, accelerometers, orientation sensors, vibration sensors, proximity sensors, acoustic sensors, gas-detection sensors, magnetic sensors, position sensors, flow sensors, force and load sensors, optical sensors, biosensors, touch sensors, radiation sensors, chemical sensors, any other type of sensors or a combination thereof. In certain implementations, the sensors 212, 214, 216, 218, the controller 204, the firmware register 206, and/or other components can be connected to and can communicate with each other by utilizing metal interconnects, wires, buses, network-on-a-chip components, interconnect fabrics, other types of interconnect components, or a combination thereof.

In certain implementations, the semiconductor package 201 can include any number and/or type of stack die 220, 230, 240. Stack die 220 can be connected to the base die 202, such as by utilizing through-silicon vias 209, microbumps, interposers, hybrid bonding, redistribution layers, and/or other connection mechanisms. Illustratively, in FIG. 2, the stack die 220 is shown as being connected to the base die 202 via through-silicon vias 209. The stack die 230 can be connected to the stack die 220, and the stack die 240 can be connected to stack die 230 using the same or similar connection mechanisms (e.g., through-silicon vias 209), such as those utilized for connecting the stack die 220 to the base die 202. In certain implementations, the stack die 220 can include any number of sensors, such as sensors 222, 224, 226, 228; the stack die 230 can include any number of sensors, such as sensors 232, 234, 236, 238; and the stack die 240 can include any number of sensors, such a sensors 242, 244, 246, 248.

Each of the sensors of the stack base die 202 and the stack die 220, 230, 240 can obtain sensor data associated with the location in which they sensors are installed on the base die 202 and the stack die 220, 230 240, respectively. Sensor signals including the sensor data (e.g., temperature measurements and/or other types of sensor data) can be transmitted from one or more of the sensors 212, 214,216, 218, 222, 224, 226, 228, 232, 234, 236, 238, 240, 242, 246, and 248 via the through silicon-vias 209 to the controller 204. In certain implementations, the controller 204 can analyze the sensor data and compare the sensor data to thresholds, such as thresholds indicative of or corresponding to potentially unsafe or harmful conditions that can affect the components of the system 200, the semiconductor package 201, the base die 202, the stack die 220, 230, 240, any other components, or a combination thereof. The controller 204 can generate instructions in signals to be sent via the through silicon vias 209 to one or more of the base die 202 and/or stack die 220, 230, 240 to cause one or more actions to be performed, such as if one or more thresholds are satisfied based on the comparison of the sensor data to the thresholds. For example, the actions can include, but are not limited to, throttling operations intended for a particular stack die 220, 230, 240, and/or the base die 202, deactivating and/or activating components of a particular stack die 220, 230, 240, and/or the base die 202, shifting operations intended for a particular stack die 220, 230, 240, and/or the base die 202 to another stack die 220, 230, 240 and/or the base die of the same or different semiconductor package 201, performing any other actions, or a combination thereof. In certain implementations, the controller 204 can provide the sensor data for analysis to components and/or devices external to the semiconductor package 201, such as to an external device 160. In certain implementations, the external device 160 can determine whether an action is to be performed and can provide a signal(s) to the controller 204, which can facilitate initiation of the action with respect to the stack die 220, 230, 240, and/or base die 202.

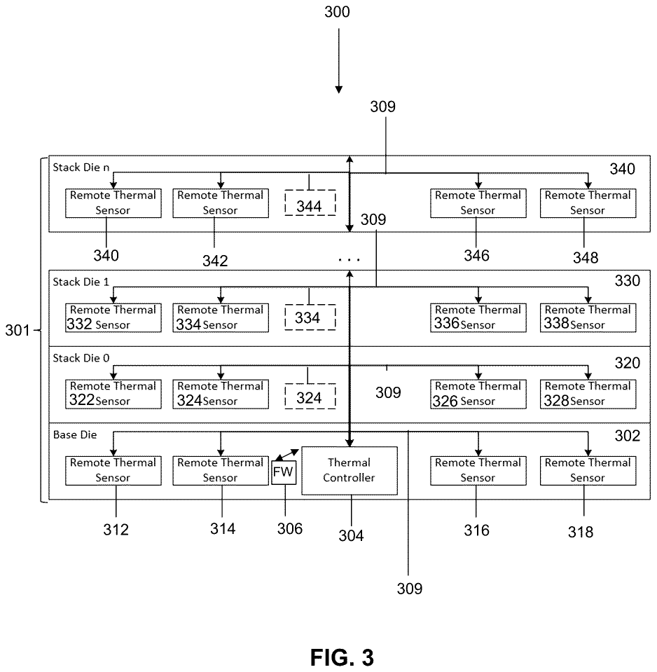

Referring now also to FIG. 3, a schematic diagram of another exemplary architecture for sensor monitoring for system die according to implementations of the present disclosure is shown. The system 300 can include incorporating controllers (e.g., controller 304) not only in the base die 302, but also in any number of stack die 320, 330, 340. In certain implementations, the system 300 can be and/or can include the systems 100, 200, modified version of systems 100, 200, the computing device 101, and/or the semiconductor package 301. In certain implementations, the components and the features and functionality of the components shown in FIG. 3 can correspond with the components and features and functionality of the components shown in FIGS. 1 and 2. Illustratively, FIG. 3 of the system 300 can include a semiconductor device or package 301 that can include a base die 302 (e.g., such as base die 102 or base die 202) and n number of stack die 320, 330, 340. In certain implementations, the base die 302 and the stack die 320, 330, 340 can be the same type of die, but in certain implementations, the base die 302 and the stack die 320, 330, 340 can be implemented using different types of die implemented utilizing different technologies. In certain implementations, the base die 302 can include a controller 304 (e.g., the same or similar to controller 104) that can be utilized to control, activate, and/or deactivate the various sensors (e.g., sensors 312, 314,316, 318, 322, 324, 326, 328, 332, 334, 336, 338, 340, 342, 346, and 348) of the system 300. In certain implementations, the controller 304 can communicate with any of the components of the system 300, the system 200, system 100, or a combination thereof. In certain implementations, the controller 304 can receive signals from an external device (e.g., external device 160), such as signals indicating operations to be performed by the components of the base die 302, the stack die 320, the stack die 330, and/or the stack die 340. In certain implementations, the base die 302 can include any components of a traditional base die, but can also include additional components, such as a firmware register 306, which can be utilized to store instructions, signals, sensor data from sensors of the base die 302 and/or the stack die 320, 330, 340, any data and/or information generated in and/or by the system 300, or a combination thereof. In certain implementations, the firmware register 306 can be included in other components of the semiconductor package 301 and/or on certain stack die 320, 330, 340.

In certain implementations, the base die 302 can be the same or similar to base die 202 and can include any number and/or type of sensors, such as, but not limited to, sensors 312, 314, 316, 318. In certain implementations, the sensors can be temperature sensors that can measure the temperature in a vicinity of the location at which the sensors 312, 314, 316, 318 are positioned. For example, illustratively in FIG. 3, four temperature sensors 312, 314, 316, 318 are shown and are positioned at different locations on the base die 302 respectively. Each sensor 312, 314, 316, 318 can measure the any type of sensor data (e.g., temperature measurements) in a vicinity of the corresponding location that each sensor 312, 314, 316, 318 is located. As described in the present disclosure, in certain implementations, the sensors 312, 314, 316, 318 can be any other type of sensors, such as, but not limited to, motion sensors, light sensors, pressure sensors, humidity sensors, accelerometers, orientation sensors, vibration sensors, proximity sensors, acoustic sensors, gas-detection sensors, magnetic sensors, position sensors, flow sensors, force and load sensors, optical sensors, biosensors, touch sensors, radiation sensors, chemical sensors, any other type of sensors or a combination thereof. In certain implementations, the sensors 312, 314, 316, 318, the controller 304, the firmware register 306, and/or other components can be connected to and can communicate with each other by utilizing metal interconnects, wires, buses, network-on-a-chip components, interconnect fabrics, other types of interconnect components, or a combination thereof.

In certain implementations, the semiconductor package 301 can include any number and/or type of stack die 320, 330, 340. In certain implementations, stack die 320 can be connected to the base die 302, such as by utilizing through-silicon vias 309, microbumps, interposers, hybrid bonding, redistribution layers, and/or other connection mechanisms. In FIG. 3, the stack die 320 is shown as being connected to the base die 302 via through-silicon vias 309. The stack die 330 can be connected to the stack die 320, and the stack die 340 can be connected to stack die 330 using through-silicon vias 309 as well. In certain implementations, the stack die 320 can include any number of sensors, such as sensors 322, 324, 326, 328; the stack die 330 can include any number of sensors, such as sensors 332, 334, 336, 338; and the stack die 340 can include any number of sensors, such a sensors 342, 344, 346, 348.

In certain implementations, one or more of the stack die 320, 330, 340, can include stack die controllers 324, 334, 344. In certain implementations, the stack die controllers 324, 334, 344 can include the features and functionality of the controller 304 (i.e., the base die controller) of the base die 302. Stack die controllers 324, 334, 344 can receive signals including sensor data from the sensors on the stack die 320, 330, 340 on which they reside. For example, stack die controller 324 can receive signals including sensor data from the sensors 322, 324, 326, and 328. In certain implementations, a stack die controller 324, 334, 344 can receive signals including sensor data from any of the sensors 312, 314,316, 318, 322, 324, 326, 328, 332, 334, 336, 338, 340, 342, 346, and 348, compare the signals to thresholds, and initiate actions based on whether the thresholds have been satisfied or not. In certain implementations, the timing of the signals that traverse the system 300 can be synchronous when stack die controllers 324, 334, 344 are present in the stack.

In certain implementations, the stack die controllers 324, 334, 344 can initiate the same or similar actions as the controller 304 can. For example, the stack die controllers 324, 334, 344, such as upon determination that the sensor data satisfies a threshold associated with a potentially harmful condition, can generate signals to activate or deactivate components of the stack die 320, 330, 340 and/or base die 302, signals to throttle (e.g., reduce) operations intended for stack die 320, 330, 340 and/or base die 302, shift operations between and/or among stack die 320, 330, 340 and/or base die 302, deactivate or activate certain sensors 312, 314,316, 318, 322, 324, 326, 328, 332, 334, 336, 338, 340, 342, 346, and 348, shift operations intended for the stack to be processed by another stack of the system 300 or other device, any other actions, or a combination thereof. In certain implementations the stack die controllers 324, 334, 344 and/or the controller 304 can characterize performance of each of the components of the stack die 324, 334, 344 and/or base die 304 based on the sensor data obtained from the sensors 312, 314,316, 318, 322, 324, 326, 328, 332, 334, 336, 338, 340, 342, 346, and 348. In certain implementations, characterizing performance can include indicating whether the stack die 324, 334, 344 and/or base die 304 are operating pursuant to specifications specified for normal operation of the stack die 324, 334, 344 and/or base die 304, indicating whether the stack die 324, 334, 344 and/or base die 304 are experiencing harmful operating conditions (e.g., temperature is too high and can cause failures or processing problems, processing is too slow, data storage is not working, etc.), indicating whether operations being processed by the semiconductor device including the stack die 324, 334, 344 and/or base die 304 are being processed as expected, indicating any other performance aspect, or a combination thereof.

FIG. 4 is a flow diagram of an exemplary method 400 for providing sensor monitoring for system die. The steps shown in FIG. 4 can be performed by any suitable circuit and/or system, including the system(s) illustrated in FIGS. 1, 2, and/or 3. In certain implementations, each of the steps shown in FIG. 4 represent an algorithm whose structure includes and/or is represented by multiple sub-steps, examples of which will be provided in greater detail below. In certain implementations, each of the steps shown in FIG. 4 can represent actions, activities, processes, and/or operations that can be performed by the components of FIGS. 1, 2 and 3. The method 400 can be adapted and/or modified to be utilized with any of the systems of FIGS. 1, 2, and 3.

As illustrated in FIG. 4 and in certain implementations, at step 402, one or more of the systems described herein can activate one or more sensors of a base die and one or more sensors of one or more stack die stacked onto the base die. For example, the controller 104 of the base die 102 can transmit one or more signals to cause one or more of the sensors 110, 124, 134, 144 to activate. In certain implementations, the signals can be transmitted up and down the semiconductor package 150 via interconnect component, such as through-silicon vias 109. In certain implementations, the controller 104 of the base die 102 can receive instructions from an external device 160 and/or components of the system 100 to activate one or more of the sensors 110, 124, 134, 144.

At step 404, the method 400 can include, in certain implementations, monitoring the one or more sensors 110 of the base die 102 and/or one or more sensors 124, 134, 144 of the stack die 120, 130, 140 that are stacked onto the base die 102, all of which can be contained in a semiconductor package 150. In certain implementations, the monitoring can be conducted by utilizing one or more of the systems described in the present disclosure. In certain implementations, for example, the monitoring can be conducted by the controller 104 of the base die 102, however, in certain implementations, the monitoring can be conducted by utilizing the external device 160, a controller of a stack die (e.g., in implementations including a controller on one or more of the stack die, such as controllers 324, 334, 344 of FIG. 3), any other components of the systems described herein, or a combination thereof.

At step 406, the method 400 can include receiving one or more signals including sensor data from one or more sensors 110 of the base die 102, the one or more sensors 124, 134, 144 of the stack die 120, 130, 140, or a combination thereof. In certain implementations, for example, the sensor data (or measurements) from each sensor 110, 124, 134, 144 can be provided in a signal generated by each corresponding sensor 110, 124, 134, 144 and each signal can be transmitted through the through-silicon vias 109 to the base die controller 104. In certain implementations, the sensors 110, 124, 134, 144 can be any type of sensor. For example, the sensors 110, 124, 134, 144 can be temperature sensors, such as, but not limited to, thermocouples, resistance temperature detectors, thermistors, semiconductor temperature sensors, any other types of temperature sensors, or a combination thereof. In certain thermocouple implementations, the thermocouple sensor can output a small voltage proportional to the temperature difference and the signal including the voltage can be provided to the controller 104 that can read the voltage measurement. In certain resistance temperature detector implementations, the electrical resistance of the material of the resistance temperature detector sensor can change with temperature. The resistance temperature detector can have a current source or voltage applied to it and the resulting voltage drop across the resistance temperature detector can be measured and provided via a signal to the controller 104 via the through-silicon vias 109.

In certain implementations involving the use of a thermistor, the thermistor can change resistance with temperature and can be made of semiconductor material(s). For example, a known bias voltage can be applied across the thermistor and a resistor. The voltage between the thermistor and the resistor can be measured at the junction between them. The voltage can be converted to resistance and then converted to a temperature using a calibration curve or equation. Other types of temperature sensors and/or other types of sensors other than temperature sensors can also be utilized to measure conditions affecting the various die of the semiconductor package 150. In certain implementations involving the use of a semiconductor temperature sensor, the sensor can output a voltage linearly proportional to the temperature. For example, the sensor can output a voltage directly proportional to the temperature, which can be read by the controller 104 and converted to a temperature using a scale factor.

At step 408, the method 400 can include comparing the received sensor data from the received signal(s) from the sensors 110, 124, 134, 144 of the base die 102 and/or stack die 120, 130, 140 to a threshold. In certain implementations, the controller 104 can perform the comparison of the sensor data to the threshold, the external device 160 can perform the comparison, any components of the system of the present disclosure can perform the comparison, or a combination thereof. In certain implementations, the threshold can be a threshold value, such as a threshold temperature, which can be the temperature at which potential damage to the semiconductor package 150, the base die 102, the stack die 120, 130, 140, and/or other components of the system 100 can occur. The threshold can also be a value at which degradation of the system 100 performance can occur, degradation of performance each the base die 102 and/or stack die 120, 130, 140 can occur, and/or potential other harmful effects can occur.

At step 410, the method 400 can include determining whether the sensor data for one or more of the sensors 110, 124, 134, 144 satisfy the threshold. For example, in certain implementations, the controller 104 and/or other components of the systems described herein, can determine whether the sensor data satisfies the threshold. If none of the sensor data from the sensors 110, 124, 134, 144 satisfy the threshold, the method 400 can proceed to step 412. At step 412, the method 400 can include continuing current or planned operation of the base die 102 and/or stack die 120, 130, 140. For example, at step 412, the components in the semiconductor package 150 can continue to operate as the components are currently running and can operate as planned.

If, however, at step 410, the sensor data for one or more of the sensors 110, 124, 134, 144 satisfy the threshold, the method 400 can proceed to step 414. At step 414, the method 400 include generating one or more signals for the base die 102 and/or stack die 120, 130 140 according to which sensor data satisfied the threshold. For example, if the sensor data for each of the sensors 110, 124, 134, 144 each satisfied the threshold, signals can be generated for each corresponding base die 102 and/or stack die 120, 130, 140 that the sensors 110, 124, 134, 144 are present on and/or are in proximity to. As another example, if only the sensor data from the sensor 124 of the stack die 120 satisfied the threshold, the signal can be generated specifically for stack die 120. In certain implementations, the signal(s) can be generated by the controller 104 of the base die 102, the external device 160, the system 100, the computing device 101, other components and/or devices, or a combination thereof. In certain implementations, the signal(s) can be utilized to initiate one or more actions for the base die 102, stack die 120, 130, 140, and/or other components of the system 100. In certain implementations, the one or more actions can include, but are not limited to, throttling operations for a particular die, deactivating a particular die, deactivating a particular component on a particular die, specifying a different die to perform operations of a particular die, activating and/or deactivating sensors on a particular die, performing any other type of action, or a combination thereof.

In certain implementations, the method 400 can proceed to step 416. At step 416, the method 400 can include transmitting the signal(s) to each die (e.g., base die 102 and/or stack die 120, 130, 140) having sensors (e.g., sensors 110, 124, 134, 144) that provided sensor data that satisfied the threshold. In certain implementations, the signals can be transmitted to each die via interconnects, such as through-silicon vias 109 to each particular die intended to receive the signal. In certain implementations, the signals can directly cause the action to be performed for a particular die. For example, the action can include throttling operations for a particular stack die 120, 130 140, deactivating a particular stack die 120, 130, 140, performing any other action, or a combination thereof. In certain implementations, a component 122, 132, 142 can be configured to receive the signal(s) and execute the actions specified in the signal(s). In certain implementations, such as where stack die include their own controllers (e.g., FIG. 3), the controllers of the stack die can execute the actions specified in the signal(s) to cause the actions to be performed. In certain implementations, the sensors 110, 124, 134, 144 can continue to operate and based on the sensor data new signals can be generated by the controller 104 and/or other components of the system 100, which can perform additional actions over time. In certain implementations, the method 400 can incorporate any of the functionality as described in the present disclosure and can be amplified and/or modified accordingly.

Based on at least the foregoing and as detailed herein, the systems and methods provide a mechanism for effective monitoring of semiconductor devices and associated metrics, such as temperature, associated with stack die, base die, and/or other components of a semiconductor package or device. In order to monitor the stack die and/or base die, sensors can be positioned on the stack die and/or base die in various locations where potential hotspots or other potentially harmful conditions can occur or are expected to occur. The monitoring can include utilizing sensors to capture sensor data (e.g., temperature data) and provide the sensor data to a controller of the base die (or stack die in implementations where controllers are implemented on the stack die), which can be utilized to characterize performance of both the stack die and the base die, and to determine whether one or more actions with respect to the stack die and base die should be performed. For example, such actions can include throttling operations intended for the stack die and/or base die when temperatures (or other metrics) exceed safe operating thresholds, selected thresholds, or a combination thereof. Other actions can include deactivating certain stack die and transferring operations intended for the deactivate stack die to other stack die and/or the base die. Further exemplary actions can include pausing operations conducted by the stack die and/or base die, transmitting signals to external devices utilizing the semiconductor package indicating potentially unsafe and/or unstable operating conditions, and/or performing other actions.

In certain implementations, the systems and methods can support stack heights of various sizes and can support semiconductor packages with any number of stack die. In certain implementations, a controller can be in the base die, the stack die, or a combination thereof. In certain implementations, the controller(s) does not need to be designed in each die of the semiconductor package. In certain implementations, the controller(s) can be in different silicon technology die, nodes, and/or components and can be provided by one or more different vendors. For example, in certain implementations, reasons for doing the foregoing can include accounting for voltages allowed, silicon technology performance, power efficiency, and/or other metrics, which can make certain technology die, nodes, and/or components more advantageous to include the controller(s). The systems and methods can be utilized to minimize the interface between the base die and the stack die and can also enable asynchronous timing between and/or among the components. In certain implementations, the stack die and the base die can utilize the same technology or be implemented in separate types of technologies. In certain implementations, certain features and functionality of the systems and methods can be inspected and/or analyzed via the stack die and/or base die connectivity, such as via interconnects. Such interconnects can be implemented by utilizing through-silicon vias and/or other types of interconnects. In certain implementations, certain features and functionality provided by the systems and methods can be inspected and/or analyzed via firmware registers and/or fuses, which can be aligned to the sensor configuration for the sensors on the stack die and/or base die.

Accordingly, the systems and methods described herein enable improved and more effective techniques for monitoring stack die, base die, or a combination thereof. Such monitoring, such as through the use of sensors, can serve to prolong the life of the semiconductor components of a semiconductor device by enabling actions to be performed in response to detection of potentially unsafe or harmful conditions. Because current stack die and base die that undergo unsafe or harmful conditions reduce the life of components of semiconductor devices, the systems and methods provided herein overcome such problems and enable effective monitoring of semiconductor components, while simultaneously minimizing the interface between the base die and stack die in various implementations.

As detailed above, the circuits, devices, and systems described and/or illustrated herein broadly represent any type or form of computing device or system capable of executing computer-readable instructions, such as those contained within the modules described herein. In their most basic configuration, these computing device(s) each include at least one memory device and at least one physical processor.

In some examples, the term “memory device” generally refers to any type or form of volatile or non-volatile storage device or medium capable of storing data and/or computer-readable instructions. In one example, a memory device stores, loads, and/or maintains one or more of the modules and/or circuits described herein. Examples of memory devices include, without limitation, Random Access Memory (RAM), Read Only Memory (ROM), flash memory, Hard Disk Drives (HDDs), Solid-State Drives (SSDs), optical disk drives, caches, variations, or combinations of one or more of the same, or any other suitable storage memory.

In some examples, the term “physical processor” generally refers to any type or form of hardware-implemented processing unit capable of interpreting and/or executing computer-readable instructions. In one example, a physical processor accesses and/or modifies one or more modules stored in the above-described memory device. Examples of physical processors include, without limitation, microprocessors, microcontrollers, Central Processing Units (CPUs), Field-Programmable Gate Arrays (FPGAs) that implement softcore processors, Application-Specific Integrated Circuits (ASICs), systems on a chip (SoCs), digital signal processors (DSPs), Neural Network Engines (NNEs), accelerators, graphics processing units (GPUs), portions of one or more of the same, variations or combinations of one or more of the same, or any other suitable physical processor.

In some implementations, the term “computer-readable medium” generally refers to any form of device, carrier, or medium capable of storing or carrying computer-readable instructions. Examples of computer-readable media include, without limitation, transmission-type media, such as carrier waves, and non-transitory-type media, such as magnetic-storage media (e.g., hard disk drives, tape drives, and floppy disks), optical-storage media (e.g., Compact Disks (CDs), Digital Video Disks (DVDs), and BLU-RAY disks), electronic-storage media (e.g., solid-state drives and flash media), and other distribution systems.

The process parameters and sequence of the steps described and/or illustrated herein are given by way of example only and can be varied as desired. For example, while the steps illustrated and/or described herein are shown or discussed in a particular order, these steps do not necessarily need to be performed in the order illustrated or discussed. The various exemplary methods described and/or illustrated herein can also omit one or more of the steps described or illustrated herein or include additional steps in addition to those disclosed.

The preceding description has been provided to enable others skilled in the art to best utilize various aspects of the exemplary implementations disclosed herein. This exemplary description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A device comprising:
a stack die comprising at least one stack die sensor; and
a base die comprising:
at least one base die sensor; and
a base die controller configured to:
receive at least one first signal including sensor data from the at least one base die sensor, the at least one stack die sensor, or a combination thereof;
compare the sensor data to a threshold; and
transmit, if the sensor data satisfies the threshold, at least second one signal to the base die, the stack die, or a combination thereof, to initiate at least one first action for the base die, the stack die, or a combination thereof.

2. The device of claim 1, wherein the base die controller is further configured to monitor the at least one stack die sensor, the at least one base die sensor, or a combination thereof.

3. The device of claim 1, wherein the base die controller is further configured to transmit an activation signal to activate operation of the at least one base die sensor, the at least one stack die sensor, or a combination thereof.

4. The device of claim 1, wherein the base die controller is further configured to transmit a deactivation signal to deactivate operation of the at least one base die sensor, the at least one stack die sensor, or a combination thereof.

5. The device of claim 1, wherein the base die controller is further configured to receive an instruction associated with the at least one first signal to initiate the at least one first action from a firmware register of the device.

6. The device of claim 1, wherein the at least one first action comprises throttling at least one operation intended for the base die, the stack die, or a combination thereof.

7. The device of claim 1, wherein the at least one first action comprises deactivating at least one component of the base die, the stack die, or a combination thereof.

8. The device of claim 1, further comprising a stack die controller configured to:
monitor the at least one stack die sensor; and
receive a signal of the at least one first signal including the sensor data from the at least one stack die sensor.

9. The device of claim 8, wherein the stack die controller is further
configured to:
compare the sensor data from the at least one stack die sensor to a stack die threshold; and
transmit, if the sensor data from the at least one stack die sensor satisfies the stack die threshold, at least one third signal to initiate at least one second action for the stack die.

10. The device of claim 8, wherein the stack die controller is further
configured to:
compare the sensor data from the at least one stack die sensor to a stack die threshold; and
maintain, if the sensor data from the at least one stack die sensor does not satisfy the stack die threshold, a current state of the stack die or a planned state for the stack die.

11. The device of claim 1, wherein the device comprises at least one through silicon via to facilitate communication between the base die and the stack die.

12. The device of claim 1, wherein the threshold corresponds to a temperature threshold for the base die, the stack die, or a combination thereof.

13. A system comprising:
a memory; and
a device communicatively linked to the memory, and comprising:
a base die comprising:
at least one base die sensor; and
a base die controller configured to:
receive at least one first signal including sensor data from the at least one base die sensor, at least one stack die sensor of a stack die in communication with the base die, or a combination thereof;
compare, based on instructions from the memory, the sensor data to a threshold;
transmit, if the sensor data satisfies the threshold, at least second one signal to the base die, the stack die, or a combination thereof, to initiate at least one first action for the base die, the stack die, or a combination thereof; and
provide the first signal, the second signal, or a combination thereof, to the memory for storage.

14. The system of claim 13, wherein the base die further comprises a processor, a communication module, or a combination thereof.

15. The system of claim 13, wherein the base die controller is further configured to:
communicate with a separate base die from a separate system; and
offload, if the sensor data satisfies the threshold, at least one operation intended for the base die, the stack die, or a combination thereof, to the separate base die.

16. The system of claim 13, where the base die controller is further configured to modify the threshold.

17. A method, comprising:
receiving, by a base die comprising at least one base die sensor, at least one first signal including sensor data from the at least one base die sensor, at least one stack die sensor of a stack die in communication with the base die, or a combination thereof;
comparing the sensor data to a threshold; and
transmitting, if the sensor data satisfies the threshold, at least one second signal to the base die, the stack die, or a combination thereof, to initiate at least one first action for the base die, the stack die, or a combination thereof.

18. The method of claim 17, further comprising communicating, by utilizing the base die, with the stack die via an interposer.

19. The method of claim 17, further comprising continuing a current state for the base die, the stack die, or a combination thereof, if the sensor data does not satisfy the threshold.

20. The method of claim 17, further comprising:
obtaining additional sensor data from the at least one base die sensor, the at least one stack die sensor, or a combination thereof;
comparing the additional sensor data to the threshold; and
transmitting, if the additional sensor data does not satisfy the threshold, at least one third signal to the base die, the stack die, or a combination thereof, to return the base die, the stack die, or a combination thereof, to a prior operational state.
